(19) United States
(12) Patent Application Publication
(10) Pub. No.: US 2023/0130652 A1
(43) Pub. Date: Apr. 27, 2023

(54) SUBSTRATE TREATING METHOD AND CHAMBER CLEANING METHOD

(71) Applicant: SEMES CO., LTD., Cheonan-si (KR)

(72) Inventors: Won Seok LEE, Seoul (KR); Young Bea YUN, Yongin-si (KR)

(73) Assignee: SEMES CO., LTD., Cheonan-si (KR)

(21) Appl. No.: 17/968,267

(22) Filed: Oct. 18, 2022

(30) Foreign Application Priority Data
Oct. 26, 2021 (KR) 10-2021-0143849

(51) Int. Cl. H01J 37/32

(52) U.S. Cl. CPC H01J 37/32862; H01J 37/32633; H01J 2237/334

(57) ABSTRACT

The inventive concept provides a substrate treating method. The substrate treating method includes treating a substrate by transferring a process plasma to a treating space of a chamber; and cleaning an exhaust space by supplying a cleaning medium to the exhaust space of the chamber which is positioned below the treating space.

### CROSS-REFERENCE TO RELATED APPLICATIONS

A claim for priority under 35 U.S.C. § 119 is made to Korean Patent Application No. 10-2021-0143849 filed on Oct. 26, 2021, in the Korean Intellectual Property Office, the entire contents of which are hereby incorporated by reference.

### BACKGROUND

Embodiments of the inventive concept described herein relate to a substrate treating method and a chamber cleaning method.

A plasma refers to an ionized gas state consisting of ions, radicals, and electrons. The plasma is generated by a very high temperature, a strong electric field, or an RF electromagnetic field. A semiconductor device manufacturing process may include an etching process of removing a thin film or foreign materials formed on a substrate such as a wafer using the plasma. The etching process is performed by colliding ions and/or radicals of the plasma with the thin film on the substrate or reacting with the thin film.

Various treating gases are used in a process of treating the substrate using the plasma. For this reason, various process by-products including particles are generated in the chamber for treating the substrate. If a process by-product is deposited in the chamber, particles may be attached to the substrate W on which a treatment is performed in the chamber, and thus the substrate W may be contaminated. In addition, it is difficult to control a pressure inside the chamber because an exhaust of the inside of the chamber does not proceed. Accordingly, it is important to maintain an inner environment of the chamber in a clean state.

In general, a substrate treating apparatus is divided into a treating space for treating the substrate and an exhaust space which is positioned under the treating space and which exhausts an atmosphere of the treating space. The process by-product which is generated in the treating space for treating the substrate are introduced and deposited into the exhaust space. Since the exhaust space is positioned relatively far from a plasma source, it is difficult to remove process by-products deposited in the exhaust space using the plasma. In addition, it is difficult to physically clean particles deposited in the exhaust space due to structural limitations in the exhaust space.

If the process by-product is continuously deposited in the exhaust space, the process by-product is floated and attached to the substrate, thereby causing a process defect. In addition, since the process by-product is deposited on the exhaust space, a smooth exhausting to the treating space does not proceed. For this reason, since a pressure of the treating space cannot be maintained constant, an efficient substrate treatment cannot be performed.

### SUMMARY

Embodiments of the inventive concept provide a substrate treating method and a chamber cleaning method for cleaning an exhaust space of a chamber.

Embodiments of the inventive concept provide a substrate treating method and a chamber cleaning method for cleaning an exhaust space even during a plasma treatment of a substrate.

Embodiments of the inventive concept provide a substrate treating method and a chamber cleaning method for cleaning an entire region of a chamber including a treating space for treating a substate and an exhaust space disposed below the treating space.

The technical objectives of the inventive concept are not limited to the above-mentioned ones, and the other unmentioned technical objects will become apparent to those skilled in the art from the following description.

The inventive concept provides a substrate treating method. The substrate treating method includes treating a substrate by transferring a process plasma to a treating space of a chamber; and cleaning an exhaust space by supplying a cleaning medium to the exhaust space of the chamber which is positioned below the treating space.

In an embodiment, the treating space and the exhaust space is divided by an exhaust baffle having a through hole which fluidly communicates the treating space and the exhaust space.

In an embodiment, the cleaning medium is a cleaning plasma generated from a cleaning gas.

In an embodiment, the cleaning plasma is generated by a remote plasma source which excites the cleaning gas and generates the cleaning plasma.

In an embodiment, the cleaning is performed by inserting the cleaning plasma to the exhaust space by a supply port which faces a side of a support unit which supports the substrate at the treating space.

In an embodiment, at least a part of a time of which the cleaning is performed overlaps with a time of which the treating is performed.

In an embodiment, the cleaning is performed additionally for a set time after the treating is performed.

In an embodiment, the cleaning is performed additionally for a set time before the treating is performed.

In an embodiment, the cleaning medium is a neutral gas which has captured an ion from a cleaning plasma which is generated by exciting a cleaning gas.

In an embodiment, the cleaning gas includes at least one of a CF₄, an NF₃, an N₂, an O₂, an F₂, an Ar, or combinations thereof.

The inventive concept provides a chamber cleaning method for cleaning a chamber having an inner space, the inner space dividing into a treating space for treating a substate by an exhaust baffle and an exhaust space, the treating space and the exhaust space fluidly communicating through a through hole formed at the exhaust baffle. The method includes cleaning the exhaust space by transferring a cleaning plasma to the exhaust space among the treating space and the exhaust space.

In an embodiment, the cleaning the exhaust space is performed while the substrate is treated by transferring a process plasma to the treating space.

In an embodiment, the cleaning the exhaust space is performed after the substrate is treated by transferring a process plasma to the treating space.

In an embodiment, the method further includes cleaning the treating space among the treating space and the exhaust space by transferring the cleaning plasma to the treating space to clean the treating space and the exhaust space.

In an embodiment, the cleaning the treating space is performed after the substrate is taken out from the treating space.

The inventive concept provides a substrate treating method. The substrate treating method includes taking-in a substrate to an inner space of a chamber, the inner space is divided into a treating space at which the substrate is treated by an exhaust baffle which surrounds a support unit supporting the substrate at the inner space and an exhaust space which exhaust an atmosphere of the treating space, and the exhaust baffle has a through hole which fluidly communicates the treating space and the exhaust space, treating the substrate by transferring a process plasma to the substrate supported on the support unit; cleaning the exhaust space by removing impurities attached to the exhaust space by transferring a cleaning plasma to the exhaust space; and taking-out the substrate from the inner space.

In an embodiment, the cleaning the exhaust space is performed together with the treating the substrate.

In an embodiment, the cleaning the exhaust space is performed after the treating the substate is completed.

In an embodiment, the method further includes a cleaning the treating space among the treating space and the exhaust space, by supplying a cleaning plasma to the treating space to clean the treating space and the exhaust space, and wherein the cleaning the exhaust space is performed together with the cleaning the treating space.

In an embodiment, a cleaning gas excited to the cleaning plasma includes at least one of a CF₄, an NF₃, an N₂, an O₂, an F₂, an Ar, or combinations thereof.

According to an embodiment of the inventive concept, an exhaust space of a chamber may be cleaned.

According to an embodiment of the inventive concept, an exhaust space may be cleaned even during a plasma treatment of a substrate.

According to an embodiment of the inventive concept, an entire region of a chamber including a treating space for treating a substrate and an exhaust space disposed below the treating space may be cleaned.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 illustrates a substrate treating apparatus according to an embodiment of the inventive concept.

FIG. 2 illustrates the substrate treating apparatus according to another embodiment of the inventive concept.

FIG. 3 schematically illustrates illustrating an enlarged view of portion C of FIG. 2.

FIG. 4 to FIG. 6 illustrate the substrate treating apparatus according to another embodiment of the inventive concept.

FIG. 7 is a flowchart of a substrate treating method according to an embodiment of the inventive concept.

FIG. 8 illustrates the substrate treating apparatus performing a substrate treating step and an exhaust space cleaning step of FIG. 7.

FIG. 9 is a flowchart of the substrate treating method according to another embodiment of the inventive concept.

FIG. 10 illustrates the substrate treating apparatus performing the substrate treating step of FIG. 9.

FIG. 11 illustrates the substrate treating apparatus performing the exhaust space cleaning step of FIG. 9.

FIG. 12 illustrates the substrate treating apparatus performing a substrate taking out step of FIG. 9.

FIG. 13 illustrates the substrate treating apparatus performing a treating space cleaning step of FIG. 9.

FIG. 14 and FIG. 15 illustrate the substrate treating apparatus according to another embodiment of the inventive concept.

### DETAILED DESCRIPTION

The inventive concept may be variously modified and may have various forms, and specific embodiments thereof will be illustrated in the drawings and described in detail. However, the embodiments according to the concept of the inventive concept are not intended to limit the specific disclosed forms, and it should be understood that the present inventive concept includes all transforms, equivalents, and replacements included in the spirit and technical scope of the inventive concept. In a description of the inventive concept, a detailed description of related known technologies may be omitted when it may make the essence of the inventive concept unclear.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Hereinafter, embodiments of the inventive concept will be described in detail with reference to the accompanying drawings.

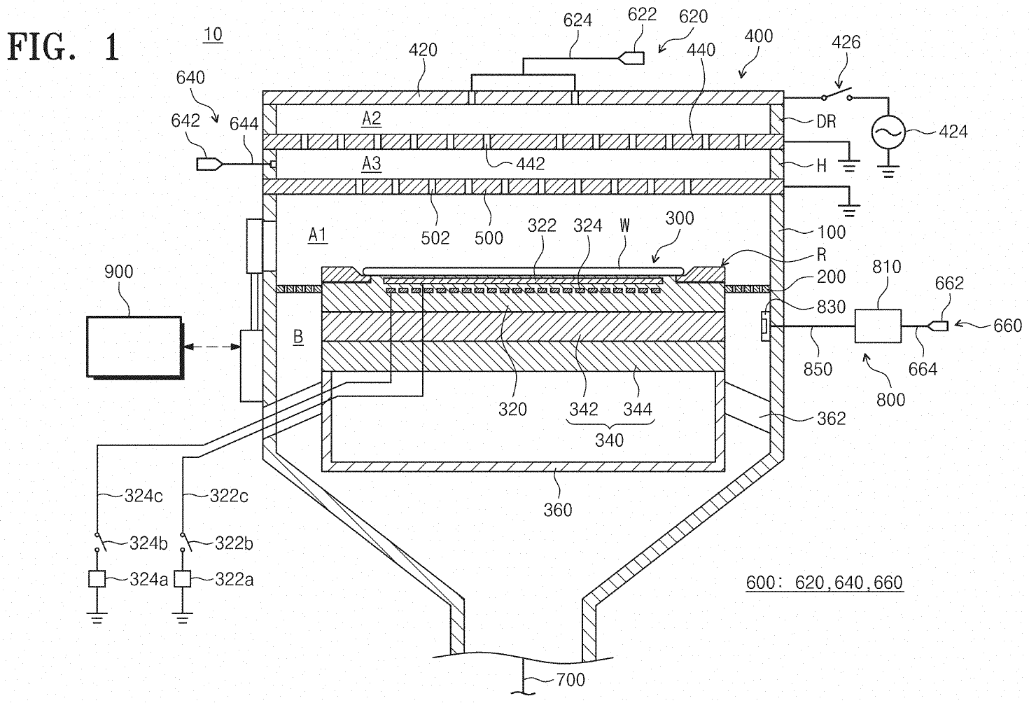

Hereinafter, an embodiment of the inventive concept will be described in detail with reference to FIGS. 1 to 12.

FIG. 1 illustrates a substrate treating apparatus according to an embodiment of the inventive concept. Referring to FIG. 1, the substrate treating apparatus 10 according to an embodiment of the inventive concept may perform a process on the substrate W. The substrate treating apparatus 10 may treat the substrate W using a plasma. For example, the substrate treating apparatus 10 may perform an etching process of removing a thin film on the substrate W using the plasma, an ashing process of removing a photoresist film, a deposition process of forming the thin film on the substrate W, or a dry cleaning process. However, the inventive concept is not limited thereto, and a plasma treatment process performed by the substrate treatment apparatus 10 may be variously modified into a known plasma treatment process.

The substrate W taken into the substrate treating apparatus 10 may be a substrate W in which a treating process has been partially performed. For example, the substrate W taken into the substrate treating apparatus 10 may be a substrate W in which an etching process, a photolithography process, or the like have been performed.

The substrate treating apparatus 10 may include a chamber 100, an exhaust baffle 200, a support unit 300, a plasma source 400, a shower head 500, a gas supply unit 600, an exhaust unit 700, a cleaning unit 800, and a controller 900.

The chamber 100 may have inner spaces A1, A2, A3, and B. The inner spaces A1, A2, A3, and B of the chamber 100 may be divided into a process space A above and an exhaust space B disposed under the treating space A by an exhaust baffle 200 to be described later. The process space A may be divided into a treating space A1 An exemplary first space), a plasma space A2 (an exemplary second space), and a mixing space A3 (an exemplary third space). Since a treatment is performed on an actual substrate W in the treating space A1, the treating space A1 may be regarded as a treating space with a narrow meaning. In addition, since the plasma space A2 and the mixing space A3 generate an etchant for treating the substrate W, it can be seen as a treating space with a wide meaning.

The treating space A1 may be a space defined by combining the exhaust baffle 200, the support unit 300, and the shower head 500 to be described later. The treating space A1 may be provided as a space in which the substrate W is treated. The plasma space A2 may be defined as a space in which a top electrode 420 to be described later and an ion blocker 440 to be described later are combined with each other. The plasma space A2 may be provided as a space in which a plasma is generated. The mixing space A3 may be defined as a space in which the ion blocker 440 and the shower head 500 are combined with each other. The mixing space A3 may be provided as a space in which the plasma from which ions are removed and a second process gas G2 supplied by a second gas supply unit 640 to be described later are mixed with each other to generate a reaction gas.

The chamber 100 may be provided in a cylindrical shape with an open top. A top electrode 420 to be described later may be positioned on an open top portion of the chamber 100. When treating the substrate W, the treating space A1 of the chamber 100 may be generally maintained in a vacuum atmosphere. An inner wall of the chamber 100 may be coated with a material capable of preventing an etching by the plasma. In an embodiment, the inner wall of the chamber 100 may be coated with a dielectric film such as a ceramic. The chamber 100 may be grounded.

An exhaust hole may be formed on a bottom surface of the chamber 100. The exhaust unit 700 may be connected to the exhaust hole. An inlet (not shown) through which the substrate W is taken in or taken out may be formed at a side of the chamber 100. The inlet may be selectively opened and closed by a door (not shown).

The exhaust baffle 200 may have a substantially ring shape when viewed from above. At least one through hole may be formed in the exhaust baffle 200. In an embodiment, a plurality of through holes may be formed in the exhaust baffle 200 in the vertical direction. The through hole formed in the exhaust baffle 200 may fluidly communicate the treating space A1 and the exhaust space B with each other. The exhaust baffle 200 may be configured to surround the support unit 300 to be described later. For example, the exhaust baffle 200 may be configured to surround the support unit 300 when viewed from above. The exhaust baffle 200 may extend from a circumference of the support unit 300 to a sidewall of the chamber 100.

The exhaust baffle 200 may divide the inner spaces A1, A2, A3, and B of the chamber 100 into a treating space A1 and an exhaust space B. The treating space A1 may be defined an area above the exhaust baffle 200. The treating space A1 may be provided as a space in which a substrate is treated. The exhaust space B may be defined as an area below the exhaust baffle 200. The exhaust space B may be provided as a space for exhausting a gas, process by-products, or the like supplied to the treating space A1 to an outside of the chamber 100. In an embodiment, process by-products or the like generated in the treating space A1 may pass through the through hole of the exhaust baffle 200 and be transmitted to the exhaust unit 700. The process by-products transmitted to the exhaust unit 700 may be exhausted to the outside of the chamber 100.

The support unit 300 may be configured to support the substrate W in the inner spaces A1, A2, A3, and B of the chamber 100. For example, the support unit 300 may be configured to support the substrate W in the treating space A1. The support unit 300 may be provided to be upwardly spaced apart from a bottom surface of the chamber 100. The support unit 300 supports the substrate W.

The support unit 300 may include an electrostatic chuck which adsorbs the substrate W using an electrostatic force. Alternatively, the support unit 300 may support the substrate W in various ways, such as a vacuum adsorption method or a mechanical clamping method. Hereinafter, the support unit 300 including an electrostatic chuck will be described.

The support unit 300 may include a dielectric plate 320, a support plate 342, 344, a bottom body 360, and a ring member R. The dielectric plate 320 is positioned on a top end of the support unit 300. The dielectric plate 320 may be provided as a dielectric substrate having a disk shape. In an embodiment, the dielectric plate 320 may be made of a ceramic material. The dielectric plate 320 may have a support surface for supporting the substrate W. The substrate W is placed on a top surface of the dielectric plate 320. The top surface of the dielectric plate 320 has a radius smaller than that of the substrate W. If the substrate W is placed on the top surface of the dielectric plate 320, an edge region of the substrate W may be positioned outside the dielectric plate 320. The electrode 322 and the heater 324 may be buried in the dielectric plate 320. The electrode 322 may be positioned above the heater 324.

The electrode 322 may be provided at a position overlapping the substrate W when viewed from above. The electrode 322 is electrically connected to a first power source 322a. The first power source 322a may include a DC power. A first switch 322b is installed between the electrode 322 and the first power source 322a. The electrode 322 may be electrically connected to the first power source 322a by turning on/off the first switch 322b. If the first switch 322b is turned on, a DC current is applied to the electrode 322. If a current is applied to the electrode 322, the electrode 322 may form an electric field by an electrostatic force capable of chucking the substrate W. The electric field may transmit a force which causes the substrate W to be chucked in a direction toward the dielectric plate 320. Accordingly, the substrate W is adsorbed to the dielectric plate 320. In addition, the electric field may allow ions described later to flow straight toward the substrate W. That is, the electric field may allow ions to have an anisotropy.

The heater 324 is electrically connected to the second power source 324a. A second switch 324b may be installed between the heater 324 and the second power source 324a. The heater 324 may be electrically connected to the second power source 324a by turning on/off the second switch 324b. The heater 324 generates a heat by resisting a current applied from the second power source 324a. The generated heat is transferred to the substrate W through the dielectric plate 320. The substrate W may be maintained at a predetermined temperature by the heat generated by the heater 324. The heater 324 may include a coil having a spiral shape. A plurality of heaters 324 are provided. The heater 324 may be provided in different regions of the dielectric plate 320. For example, the heater 324 for heating a central region of the dielectric plate 320 and a heater 324 for heating an edge region of the dielectric plate 320 may be provided, and these heaters 324 may independently control a degree of a heat generation. The heater 324 may be a heating element such as a tungsten. However, the type of the heater 324 is not limited thereto, and may be variously modified to a known heater 324.

In the above-described example, it has been described that the heater 324 is provided in the dielectric plate 320, but the inventive concept is not limited thereto. The heater 324 may not be provided in the dielectric plate 320.

The support plate 342, 344 is positioned under the dielectric plate 320. The support plate 342, 344 may be provided in a disk shape when viewed from above. The support plate 342, 344 may be provided with an area corresponding to that of the dielectric plate 320. The support plate 342, 344 may be made of an insulating material. The support plate 342, 344 may electrically insulate the dielectric plate 320 from the bottom body 360 to be described later.

In the above-described example, the support plate 342, 344 is formed of an insulating material, but is not limited thereto. The support plate 342, 344 may include an electrode plate 342 and an insulating plate 344.

The electrode plate 342 may be positioned below the dielectric plate 320. The electrode plate 342 may be provided in a disk shape. The electrode plate 342 may be made of a conductive material. In an embodiment, the electrode plate 342 may be made of an aluminum material. A top central region of the electrode plate 342 may have an area corresponding to a surface of the dielectric plate 320. The electrode plate 342 may include a metal plate. According to an embodiment, an entire region of the electrode plate 342 may be provided as a metal plate. In an embodiment, a high-frequency power may be applied to the electrode plate 342. A cooling flow path (not shown) may be provided in the electrode plate 342.

The insulating plate 344 may be positioned below the electrode plate 342. The insulating plate 344 may be provided in a disk shape when viewed from above. The insulating plate 344 may be provided with an area corresponding to that of the electrode plate 342. The insulating plate 344 may be made of an insulating material. The insulating plate 344 may electrically insulate the electrode plate 342 from the bottom body 360 to be described later.

The bottom body 360 is provided under the support plate 342, 344. The bottom body 360 may have a cylindrical shape with an open top when viewed from above. A lifting/lowering member (not shown) for lifting/lowering the substrate W and/or the ring member R to be described later may be positioned in the inner space of the bottom body 360.

The bottom body 360 has a connection member 362. The connection member 362 connects an outer surface of the bottom body 360 with the inner wall of the chamber 100. A plurality of connection members 362 may be provided on the outer surface of the bottom body 360 at regular intervals. The connection member 362 supports the support unit 300 inside the chamber 100. In addition, the connection member 362 is connected to the inner wall of the chamber 100, so that the bottom body 360 is electrically grounded. A first power line 322c connected to the first power source 322a, a second power line 324c connected to the second power source 324a, and the like extend to the outside of the chamber 100 through an inner space of the connection member 362.

The plasma source 400 excites a gas in the chamber 100 into a plasma state. The plasma source 400 may excite a process gas in the chamber 100 into a plasma state. In an embodiment, the plasma source 400 may excite a first process gas G1 to be described later in the chamber 100 into a plasma state. The plasma source 400 may include a top electrode 420 and an ion blocker 440.

The top electrode 420 may have a plate shape. The top electrode 420 may be positioned at an open top end of the chamber 100. The top electrode 420 may be positioned above the ion blocker 440 to be described later. The top electrode 420 may be disposed to face the ion blocker 440. The top electrode 420 may generate the plasma. In an embodiment, the top electrode 420 may generate a process plasma.

A power may be applied to the top electrode 420 by top power source modules 424 and 426 of the substrate treating apparatus 10. The top power source modules 424 and 426 may include a top power source 424 and a top power source switch 426. The top power source 424 may be provided as a high frequency RF power source. The high frequency RF power may be provided as a high bias power RF power source. The power may be applied to the top electrode 420 according to on/off of the top power switch 426. If a power is applied to the top electrode 420, an electric field is formed between the ion blocker 440 and the top electrode 420 to be described later, which function as a counter electrode.

The top electrode 420 may generate the process plasma by exciting a first process gas G1 to be described later at the plasma space A2 defined as a combined space. An insulating member DR provided as an insulating material may be disposed between the top electrode 420 and the ion blocker 440. The insulating member DR may have a ring shape when viewed from above.

The ion blocker 440 may collect ions from the plasma generated in the plasma space A2. The ion blocker 440 may be disposed in a path in which the plasma generated in the plasma space A2 is transferred to the treating space A1 to collect the ions of the plasma generated in the plasma space A2. Accordingly, if the plasma generated in the plasma space A2 passes through the mixing space A3 to the treating space A1, the plasma from which the ions have been substantially removed, that is, a neutral gas (radical), may be transferred to the mixing space A3 and the treating space A1.

The ion blocker 440 may be disposed below the top electrode 420. The ion blocker 440 may be positioned above the support unit 300. The ion blocker 440 may be positioned above the shower head 500 to be described later. In an embodiment, the ion blocker 440 may be positioned between the support unit 300 and the top electrode 420. In an embodiment, the ion blocker 440 may be positioned between the top electrode 420 and the shower head 500. The ion blocker 440 may be positioned to face the top electrode 420. The ion blocker 440 and the shower head 500 to be described later may be combined with each other to define the mixing space A3.

In addition, the ion blocker 440 may be grounded to function as an electrode facing each other with the top electrode 420. A plurality of through holes 442 may be formed at the ion blocker 440. The through holes 442 may be formed to vertically penetrate the ion blocker 440. The through holes 442 may fluidly communicate the plasma space and the mixing space.

The shower head 500 may be disposed at the inner spaces A1, A2, A3, and B of the chamber 100. The shower head 500 may be positioned under the ion blocker 440. The shower head 500 may be positioned above the support unit 300. In an embodiment, the shower head 500 may be positioned between the support unit 300 and the ion blocker 440. The shower head 500 may be disposed to face the ion blocker 440.

The shower head 500 may be grounded. A plurality of holes 502 may be formed at the shower head 500. The holes 502 may be formed to extend vertically from a top surface to a bottom surface of the shower head 500. The holes 502 may fluidly communicate a fluid flowing in the treating space A1 and the plasma space A2.

The heating member H may be disposed on a top portion of the shower head 500. The heating member H may be a ring heater having a ring shape when viewed from above. The heating member H may generate a heat to increase a temperature of the mixing space A3 to more effectively generate a reaction gas by reacting the process plasma from which ions are removed with a second process gas G2 to be described later.

The gas supply unit 600 may supply the process gas and a cleaning gas into the chamber 100. In an embodiment, the gas supply unit 600 may supply a first process gas G1, a second process gas G2, and a cleaning gas into the chamber 100. The gas supply unit 600 may include a first gas supply unit 620, a second gas supply unit 640, and a third gas supply unit 660.

The first gas supply unit 620 may supply the first process gas G1 into the chamber 100. The first gas supply unit 620 may supply the first process gas G1 to the plasma space A2. In an embodiment, the first gas supply unit 620 may supply the first process gas G1 to a space between the top electrode 420 and the ion blocker 440. The first gas supply unit 620 may directly inject the first process gas G1 into the plasma space A2 and indirectly supply the first process gas G1 into the mixing space A3 and the treating space A1.

The first gas supply unit 620 may include a first gas supply source 622 and a first gas channel 624. An end of the first gas channel 624 may be connected to the first gas supply source 622, and the other end thereof may communicate with the plasma space A2. The first process gas G1 may be a fluorine-containing gas containing a fluorine. For example, the first process gas G1 may be an NF₃. Optionally, the first process gas G1 may further include one or a plurality of an He, an Ar, an Xe, or an N₂.

The second gas supply unit 640 may supply the second process gas G2 into the chamber 100. The second gas supply unit 640 may supply the second process gas G2 to the mixing space A3. The second gas supply unit 640 may supply the second process gas G2 to a space between the ion blocker 440 and the shower head 500. In an embodiment, the second gas supply unit 640 may be installed on a sidewall of the chamber 100 disposed between the ion blocker 440 and the shower head 500. The second gas supply unit 640 may directly inject the second process gas G2 into the mixing space A3 to indirectly supply the second process gas G2 to the treating space A1 at which the substrate W is treated. The second gas supply unit 640 may include a second gas supply source 642 and a second gas channel 644. An end of the second gas channel 644 may be connected to the second gas supply source 642, and the other end thereof may communicate with the mixing space A3. The second process gas G2 may be a gas containing a hydrogen. For example, the second process gas G2 may be an NH₃.

In the aforementioned embodiment, it has been described that the first gas supply unit 620 and the second gas supply unit 640 are separately provided, but the inventive concept is not limited to it. The first gas supply unit 620 and the second gas supply unit 640 may have channels branched from a single gas supply unit to the plasma space A2 and the mixing space A3, and may inject the first process gas G1 into the plasma space A2 and the second process gas G2 into the mixing space A3.

The third gas supply unit 660 may supply a cleaning gas to the cleaning unit 800 to be described later. In an embodiment, the third gas supply unit 660 may supply a first cleaning gas G3 to a remote plasma source 810 to be described later. The third gas supply unit 660 may include a third gas supply source 662 and a third gas channel 664. An end of the third gas channel 664 may be connected to the third gas supply source 662, and the other end thereof may be connected to the remote plasma source 810. The first cleaning gas G3 supplied by the third gas supply unit 660 can include at least one of an O₂, an N₂, an F₂, an Ar, a CF₄, an NF₃, or combinations thereof.

The exhaust unit 700 may discharge the first process gas G1, the second process gas G2, and the process by-products supplied to the treating space A1. In an embodiment, if the gas and process by-products from the treating space A1 are introduced into the exhaust space B through the exhaust baffle 200, the exhaust unit 700 may emit the gas to the outside of the chamber 100. The exhaust unit 700 may adjust a pressure of the treating space A1. The exhaust unit 700 may include a depressurizing member such as an exhaust line and a pump. An end of the exhaust line may be connected to an exhaust hole of the chamber, and the other end thereof may be connected to the depressurizing member.

The cleaning unit 800 may clean the inside of the chamber 100. The cleaning unit 800 may supply a cleaning medium CM to the exhaust space B. The cleaning medium CM may be a first cleaning plasma generated by exciting a first cleaning gas supplied by the third gas supply unit 660. The cleaning unit 800 may clean the exhaust space B. The cleaning unit 800 may clean process by-products introduced from the treating space A1 to the exhaust space B through the exhaust baffle 200. The cleaning unit 800 may include a remote plasma source 810, a supply port 830, and a remote channel 850.

The remote plasma source 810 may generate a first cleaning plasma from the first cleaning gas supplied from a third gas supply unit 660. The remote plasma source 810 may be a capacitive coupled plasma (CCP), an inductively coupled plasma (ICP), or a microwave plasma.

The supply port 830 may be installed on an inner wall of the chamber 100. The supply port 830 may be installed to face the side of the support unit 300. The supply port 830 may be positioned in the exhaust space B. The supply port 830 may be positioned below the exhaust baffle 200. The supply port 830 may be connected to a remote channel 850. An end of the remote channel 850 may be connected to the supply port 830, and the other end thereof may be connected to the remote plasma source 810. A diffusion unit (not shown) may be provided at the supply port 830. The diffusion unit (not shown) may disperse the first cleaning plasma so that the first cleaning plasma may be diffused into the exhaust space B. The diffusion unit (not shown) may be provided as a diffuser discharged by a spray method.

The supply port 830 may supply the first cleaning plasma to the exhaust space B. The supply port 830 may be positioned to directly supply the first cleaning plasma to the exhaust space B. The first cleaning plasma generated from the remote plasma source 810 may clean process by-products or the like existing inside the exhaust space B through the supply port 830. Accordingly, in addition to the treating space A1 at which the substrate W is treated, by cleaning process by-products which may be deposited in the exhaust space B, a contamination to a bottom region of the chamber 100 can be minimized. In addition, if process by-products are deposited in the exhaust space B, a gas flow in the treating space A1 by the exhaust unit 700 may vary. According to an embodiment of this invention, the cleaning unit 800 cleans the exhaust space B, thereby minimizing a change in the gas flow in the treating space A1.

The controller 900 may control the plasma source 400, the gas supply unit 600, and the remote plasma source 810. The controller may comprise a process controller consisting of a microprocessor (computer) that executes a control of the substrate treating apparatus, a user interface such as a keyboard via which an operator inputs commands to manage the substrate treating apparatus, and a display showing the operation situation of the substrate treating apparatus, and a memory unit storing a treating recipe, i.e., a control program to execute treating processes of the substrate treating apparatus by controlling the process controller or a program to execute components of the substrate treating apparatus according to data and treating conditions. In addition, the user interface and the memory unit may be connected to the process controller. The treating recipe may be stored in a storage medium of the storage unit, and the storage medium may be a hard disk, a portable disk, such as a CD-ROM or a DVD, or a semiconductor memory, such as a flash memory.

If the substrate W is taken into the chamber 100 and seated in the support unit 300, the controller 900 may control the first gas supply unit 620 to supply the first process gas G1 to the plasma space A2. In addition, the second gas supply unit 640 may be controlled to supply the second process gas G2 to the mixing space A3. In addition, a top switch 426 may be controlled so that the top switch 426 is turned on so that the high-frequency power is applied to the top electrode 420.

Accordingly, the first process gas G1 is excited by the top electrode 420 and the ion blocker 440, and the process plasma is generated in the plasma space A2. The process plasma may include ions, electrons, and radicals. The process plasma generated in the plasma space A2 flows to the mixing space A3 through the ion blocker 440. In this process, the process plasma flows into the mixing space A3 in a state in which ions and/or electrons are removed by through holes 442 formed in the grounded ion blocker 440. That is, the radicals may flow in the mixing space A3. The radicals present in the mixing space A3 and the second process gas G2 supplied to the mixing space A3 may be mixed to reacted. A reaction gas (etchant) generated by a reaction of the second process gas G2 and radicals, flows through the shower head 500 into the treating space A1 and acts on the substrate W. For example, the reaction gas may include an NH₄F or an HF. The reaction gas reacts with the thin film on the substrate W, thereby forming reaction by-products on the substrate. The thin film may be a material including a silicon. The thin film may be a silicon oxide or a silicon nitride. For example, the thin film may be a SiO₂ or a Si₃N₄. The reaction by-products may be an (NH₄)₂SiF₆. During a treating of the substrate, the substrate is heated by the heater 324, and thus reaction by-products may be removed from the substrate W.

While treating the substrate W with the process plasma, the controller 900 may control the third gas supply unit 660 to supply the first cleaning gas to the remote plasma source 810. The controller 900 may control the remote plasma source 810 to excite the first cleaning gas from the remote plasma source 810. The first cleaning plasma generated from the first cleaning gas supplied to the remote plasma source 810 may be supplied to the exhaust space B through the supply port 830. Accordingly, the exhaust space B may be cleaned by the first cleaning plasma. The process by-products or the like deposited in the exhaust space B may be cleaned by the first cleaning plasma.

According to the above-described embodiment of the inventive concept, a cleaning of the exhaust space B positioned under the treating space A1 may be performed even during a plasma treatment of the substrate W on the treating space A1. The process by-products deposited in the exhaust space B may be controlled. Accordingly, by maintaining an inside of the exhaust space B in a clean state, it is possible to induce a smooth airflow flow not only to the exhaust space B but also to the treating space A1, the plasma space A2, and the mixing space A3. As the exhaust of each space is smoothly performed, the pressure inside the treating space A1 in which the substrate W is treated may be easily controlled. For this reason, if the plasma treatment process for the substrate W is performed, a process rate for the substrate W may be kept constant.

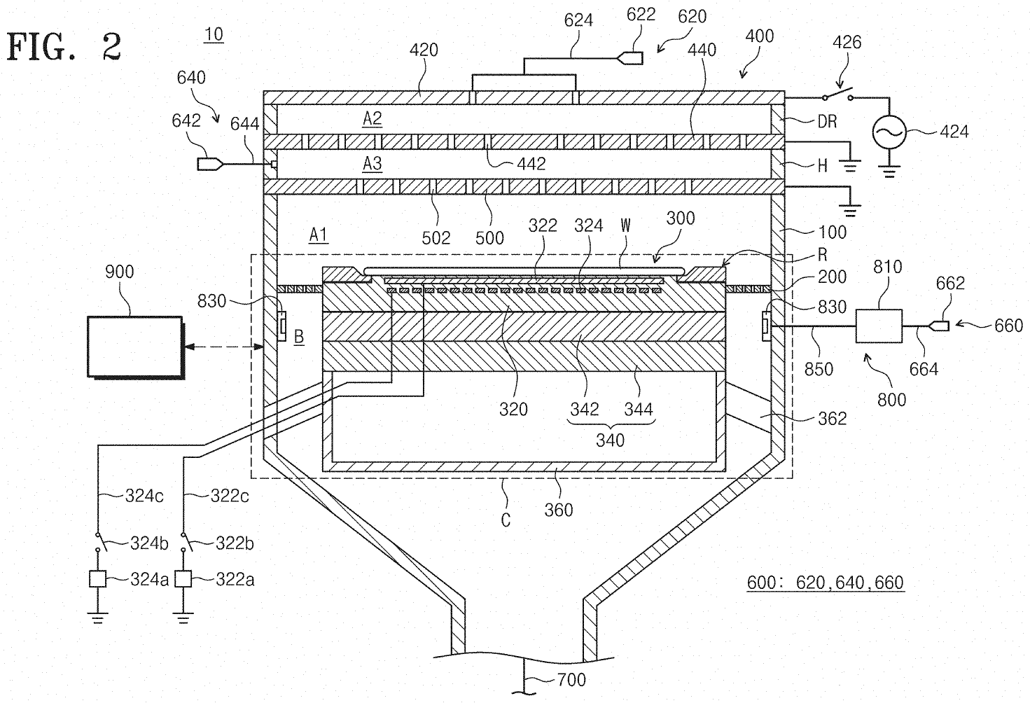

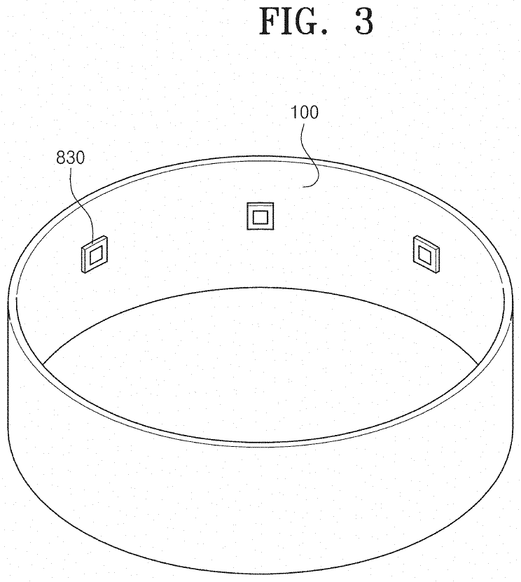

FIG. 2 illustrates the substrate treating apparatus according to another embodiment of the inventive concept. FIG. 3 schematically illustrates illustrating an enlarged view of portion C of FIG. 2. Hereinafter, the substrate treating apparatus according to another embodiment of the inventive concept will be described with reference to FIG. 2 and FIG. 3. An embodiment of the inventive concept described below is provided mostly similar to the embodiment described above, except for an exhaust port. Accordingly, a description of a similarly provided configuration in order to prevent an overlapping of content will be omitted.

The supply port 830 may be installed on an inner wall of the chamber 100. The supply port 830 may be positioned in the exhaust space B. The supply port 830 may be positioned below the exhaust baffle 200. In an embodiment, the supply port 830 may be positioned between the exhaust baffle 200 and the exhaust hole 110. A plurality of supply ports 830 may be provided. The supply port 830 may be provided to be spaced apart from each other along a circumference of the inner wall of the chamber 100. Each of the plurality of supply ports 830 may supply a first cleaning plasma to different regions in the exhaust space B.

The supply ports 830 may each be connected to a remote channel 850. The remote channel 850 may include a main channel (not shown) and a branch channel (not shown). An end of the main channel may be connected to the remote plasma source 810. The other end of the main channel may be branched into the branch channel. A plurality of branch channels may be provided. An end of the branch channels may be connected to the main channel. The other ends of the branch channels may be connected to the supply ports 830, respectively. A diffusion unit (not shown) may be provided to the supply ports 830. The diffusion unit (not shown) may disperse the first cleaning plasma so that the first cleaning plasma may be diffused into the exhaust space B. The diffusion unit (not shown) may be provided as a diffuser discharged in a spray method.

The supply ports 830 may supply the first cleaning plasma to the exhaust space B. The supply ports 830 may be positioned to directly supply the first cleaning plasma to the exhaust space B. Each of the supply ports 830 may supply the first cleaning plasma to different regions in the exhaust space B. The first cleaning plasma generated from the remote plasma source 810 may clean process by-products or the like existing inside the exhaust space B through the supply port 830. Accordingly, in addition to the treating space A1 at which the substrate W is treated, by cleaning process by-products which may be deposited in the exhaust space B, a contamination to a bottom region of the chamber 100 can be minimized.

Unlike the above-described embodiment, an on/off valve (not shown) may be provided to the branch channels. The valves (not shown) provided to the branch channel may be controlled by the controller 900. Accordingly, the first cleaning plasma may be selectively supplied to the highly contaminated area according to a severity of a contamination inside the exhaust space B by the plurality of supply ports 830 which supply the first cleaning plasma to different areas on the exhaust space B.

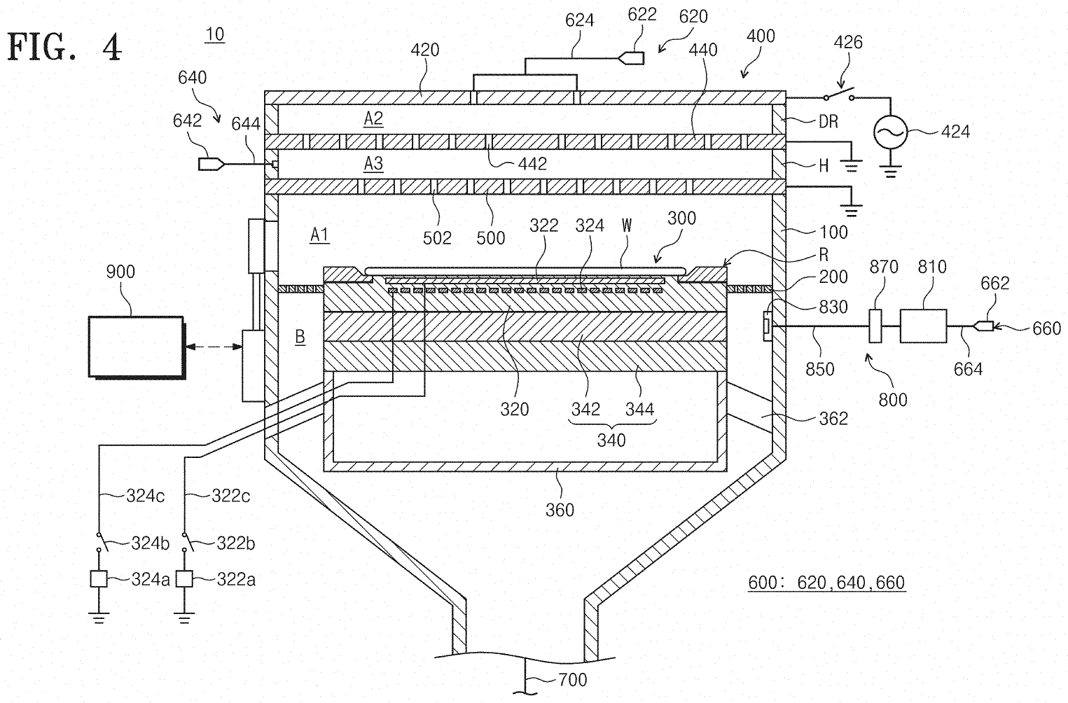

FIG. 4 to FIG. 6 illustrate the substrate treating apparatus according to another embodiment of the inventive concept. The description of the substrate treating apparatus according to another embodiment described below is similar to the description of the substrate treating apparatus in FIG. 1 and FIG. 2, and the description of the overlapping configuration is omitted below.

Referring to FIG. 4, the cleaning unit 800 may clean the inside of the chamber 100. The cleaning unit 800 may clean the exhaust space B. The cleaning unit 800 may clean process by-products introduced from the treating space A1 to the exhaust space B through the exhaust baffle 200. The cleaning unit 800 may include a remote plasma source 810, a supply port 830, and an ion trap 870.

The remote plasma source 810 may generate the first cleaning plasma from the first cleaning gas G3 supplied from the third gas supply unit 660. The remote plasma source 810 may be a capacitive coupled plasma (CCP), an inductively coupled plasma (ICP), or a microwave plasma.

The supply port 830 may be installed on an inner wall of the chamber 100. The supply port 830 may be positioned in the exhaust space B. The supply port 830 may be positioned below the exhaust baffle 200. In an embodiment, the supply port 830 may be positioned between the exhaust baffle 200 and the exhaust hole 110. The supply port 830 may be connected to the remote channel 850. An end of the remote channel 850 may be connected to the supply port 830, and the other end thereof may be connected to the remote plasma source 810. A diffusion unit (not shown) may be provided at the supply port 830. The diffusion unit (not shown) may disperse the first cleaning plasma so that the first cleaning plasma may be diffused into the exhaust space B. The diffusion unit (not shown) may be provided as a diffuser discharged by a spray method.

The ion trap 870 may be positioned between the supply port 830 and the remote plasma source 810. The ion trap 870 may be provided inside the remote channel 850. The ion trap 870 may be provided in a plate shape. A lengthwise direction of the ion trap 870 may be provided in the remote channel 850 in a direction perpendicular to a lengthwise direction of the remote channel 850. The ion trap 870 may be provided with a plurality of through holes. The through-hole may penetrate the ion trap 870 in an up/down direction. The ion trap 870 may capture ions included in the first cleaning plasma generated from the remote plasma source 810. The first cleaning plasma, i.e., neutral gas (radical), from which ions are removed by the ion trap 870 may be supplied to the exhaust space B through the supply port 830. Accordingly, the radicals may be supplied to the exhaust space B. In the first cleaning plasma generated from the remote plasma source 810, ions may be removed by the ion trap 870 and process by-products present in the exhaust space B may be cleaned with radicals through the supply port 830. Accordingly, in addition to the treating space A1 in which the substrate W is treated, the process by-products which may be deposited in the exhaust space B are more efficiently cleaned, thereby minimizing a contamination of the bottom region of the chamber 100.

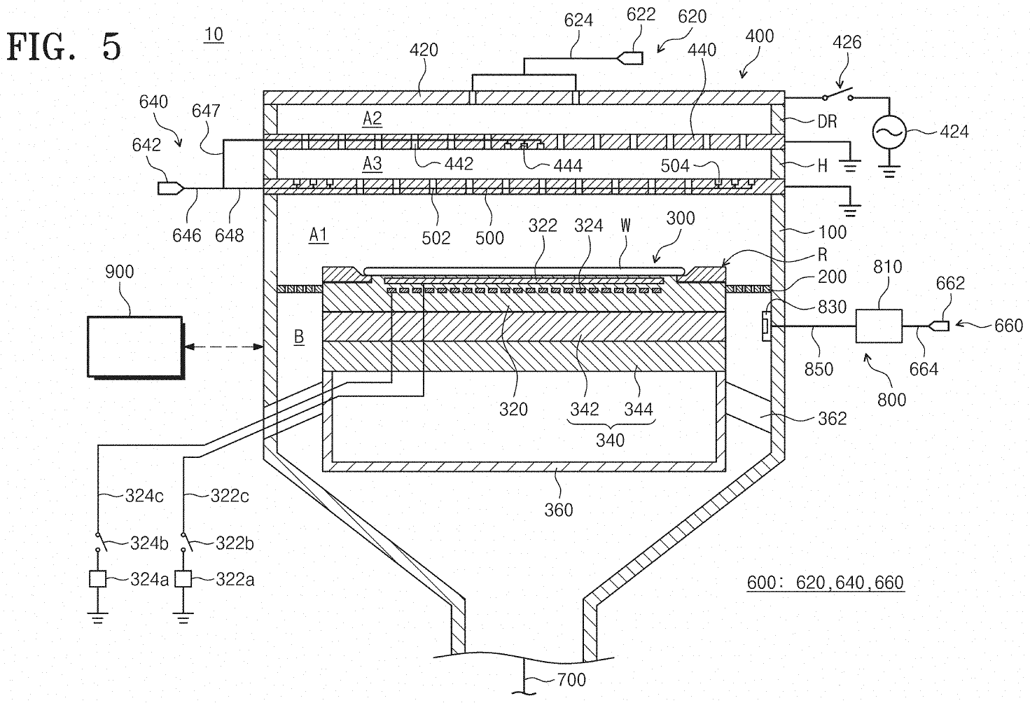

Referring to FIG. 5, the second gas supply unit 640 may supply the second process gas G2 into the chamber 100. The second gas supply unit 640 may supply the second process gas G2 to the mixing space A3. The second gas supply unit 640 may supply the second process gas G2 to a space between the ion blocker 440 and the shower head 500. The second gas supply unit 640 may include a second gas supply source 642, a main gas line 646, a first branch line 647, and a second branch line 648.

An end of the main gas line 646 may be connected to the second gas supply source 642. Another end of the main gas line 646 may be branched into the first branch line 647 and the second branch line 648. The first branch line 647 may be connected to a gas supply port 444 to be described later. The second branch line 648 may be connected to a gas inlet 504 to be described later.

A gas supply port 444 may be formed at the ion blocker 440. The gas supply port 444 may be provided in a central region of the ion blocker 440. The gas supply port 444 may be installed at a bottom end of the ion blocker 440. The gas supply port 444 may be installed at the bottom end of the ion blocker 440 to supply the second process gas G2 toward the mixing space A3. Accordingly, the gas supply port 444 may supply the second process gas G2 to the mixing space A3.

A gas inlet 504 may be formed at the shower head 500. The gas inlet 504 may be provided in an edge area of the shower head 500. In an embodiment, the gas inlet 504 may be installed on a top end of the shower head 500. The gas inlet 504 may be installed at the top end of the shower head 500 to supply the second process gas G2 toward the mixing space A3. Accordingly, the gas injection port 504 may supply the second process gas G2 to the mixing space A3. By discharging the second process gas G2 from a top and a bottom of the mixing space A3, respectively, the radicals from which electrons and/or ions included in the process plasma are removed may efficiently react with the second process gas G2.

In the above-described embodiment, it has been described that the gas supply port 444 is provided at the central region of the ion blocker 440, but is not limited thereto. The gas supply port 444 may be formed in an entire region of the ion blocker 440. In addition, the gas supply port 444 may be formed at an edge region of the ion blocker 440.

In addition, in the above embodiment, the gas inlet 504 is provided at the edge area of the shower head 500 as an example, but is not limited to it. The gas inlet 504 may be formed in an entire area of the shower head 500. In addition, the gas inlet 504 may be formed at a central area of the shower head 500.

In addition, unlike the above-described embodiment, only one of the gas supply ports 444 and the gas injection port 504 which supply the second process gas G2 to the mixing space A3 may be provided.

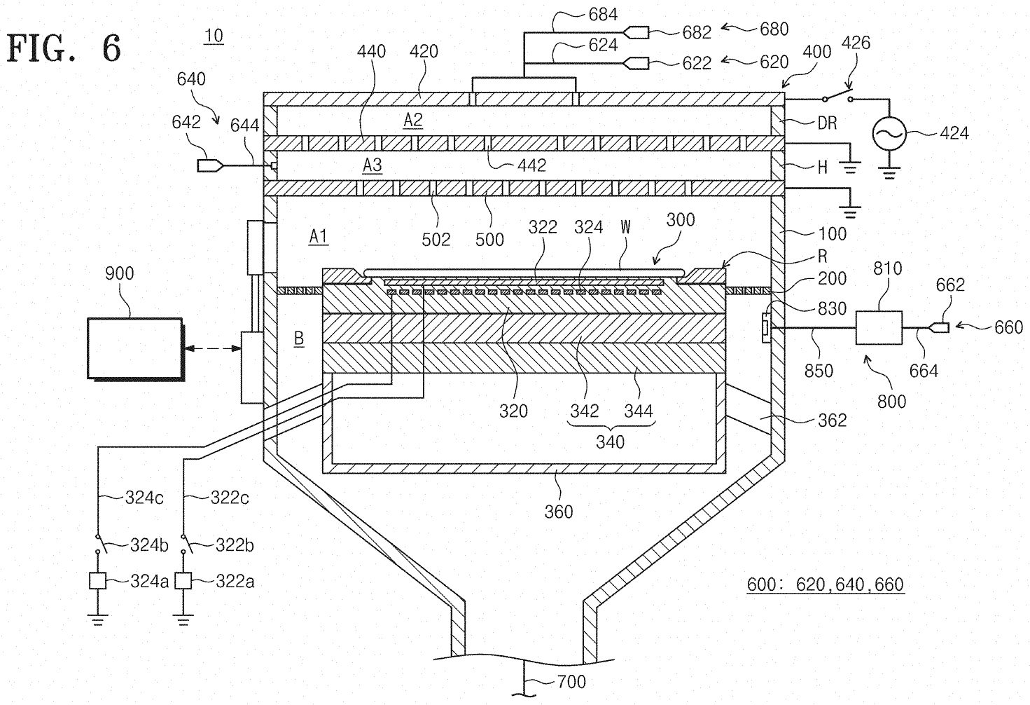

Referring to FIG. 6, the gas supply unit 600 may supply the process gas and the cleaning gas into the chamber 100. In an embodiment, the gas supply unit 600 may supply the first process gas G1, the second process gas G2, the first cleaning gas, and the second cleaning gas G4 into the chamber 100. The gas supply unit 600 may include a first gas supply unit 620, a second gas supply unit 640, a third gas supply unit 660, and a fourth gas supply unit 680.

The first gas supply unit 620 may supply the first process gas G1 into the chamber 100. The first gas supply unit 620 may supply the first process gas G1 to the plasma space A2. In an embodiment, the first gas supply unit 620 may supply the first process gas G1 to a space between the top electrode 420 and the ion blocker 440. The first gas supply unit 620 may inject the first process gas G1 into the plasma space A2 to supply the first process gas G1 into the mixing space A3 and the treating space A1. The first gas supply unit 620 may include a first gas supply source 622 and a first gas channel 624. An end of the first gas channel 624 may be connected to the first gas supply source 622, and the other end thereof may communicate with the plasma space A2.

The first process gas G1 may be a fluorine-containing gas. For example, the first process gas G1 may be an NF₃. Optionally, the first process gas G1 may further include one or a plurality of an He, an Ar, an Xe, or an N₂.

The second gas supply unit 640 may supply the second process gas G2 into the chamber 100. The second gas supply unit 640 may supply the second process gas G2 to the mixing space A3. The second gas supply unit 640 may supply the second process gas G2 to a space between the ion blocker 440 and the shower head 500. In an embodiment, the second gas supply unit 640 may be installed on a sidewall of the chamber 100 positioned between the ion blocker 440 and the shower head 500. The second gas supply unit 640 may supply the second process gas G2 to the treating space A1 at which the substrate W is treated by injecting the second process gas G2. The second gas supply unit 640 may include a second gas supply source 642 and a second gas channel 644. An end of the second gas channel 644 may be connected to the second gas supply source 642, and the other end thereof may communicate with the mixing space A3. The second process gas G2 may be a gas containing a hydrogen. For example, the second process gas G2 may be an NH₃.

In the aforementioned embodiment, it has been described that the first gas supply unit 620 and the second gas supply unit 640 are separately provided, but the inventive concept is not limited to it. The first gas supply unit 620 and the second gas supply unit 640 may have channels branched from a single gas supply unit to the plasma space A2 and the mixing space A3, and may inject the first process gas G1 into the plasma space A2 and the second process gas G2 into the mixing space A3.

The third gas supply unit 660 may supply the first cleaning gas G3 to the cleaning unit 800. In an embodiment, the third gas supply unit 660 may supply the first cleaning gas G3 to the remote plasma source 840. The third gas supply unit 660 may include a third gas supply source 662 and a third gas channel 664. An end of the third gas channel 664 may be connected to the third gas supply source 662, and the other end thereof may be connected to the remote plasma source 840. The first cleaning gas G3 supplied by the third gas supply unit 660 can include at least one of an O₂, an N₂, an F₂, an Ar, a CF₄, an NF₃, or combinations thereof.

The fourth gas supply unit 680 may supply the second cleaning gas G4 into the chamber 100. The fourth gas supply unit 680 may supply the second cleaning gas G4 to the plasma space A2. In an embodiment, the fourth gas supply unit 680 may supply the second cleaning gas G4 to a space between the top electrode 420 and the ion blocker 440. The fourth gas supply unit 680 may inject the second cleaning gas G4 into the plasma space A2 to supply the second cleaning gas G4 into the mixing space A3 and the treating space A1. The fourth gas supply unit 680 may include a fourth gas supply source 682 and a fourth gas channel 684. An end of the fourth gas channel 684 may be connected to the fourth gas supply source 682, and the other end thereof may communicate with the plasma space A2. The second cleaning gas G4 supplied by the fourth gas supply unit 680 may include at least one of an O₂, an N₂, an F₂, a Cl₂, an Ar, a CF₄, an NF₃, or combinations thereof.

The controller 900 may control the plasma source 400, the gas supply unit 600, and the remote plasma source 810. If the substrate W is taken into the chamber 100 and seated on the support unit 300, the controller 900 may control the first gas supply unit 620 to supply the first process gas G1 to the plasma space A2. In addition, the second gas supply unit 640 may be controlled to supply the second process gas G2 to the mixing space A3. In addition, the top switch 426 may be controlled so that the top switch 426 is turned on so that a high-frequency power is applied to the top electrode 420. Accordingly, the first process gas G1 is excited by the top electrode 420 and the ion blocker 440, and a process plasma is generated in the plasma space A2. The process plasma may include ions, electrons, and radicals. The process plasma generated in the plasma space A2 flows to the mixing space A3 through the ion blocker 440. In this process, the process plasma flows into the mixing space A3 in a state where ions and/or electrons are removed by the through holes 442 formed in the grounded ion blocker 440. That is, the radical may flow in the mixing space A3. The radical present in the mixing space A3 and the second process gas G2 supplied to the mixing space A3 may be mixed and reacted. The reaction gas generated by the reaction of the second process gas G2 and the radical flows through the shower head 500 into the treating space A1 and acts on the substrate W. For example, the reaction gas may include an NH₄F or a HF. The reaction gas reacts with the thin film on the substrate W, thereby forming a reaction by-product on the substrate. The thin film may be a material including a silicon. The thin film may be a silicon oxide or a silicon nitride. For example, the thin film may be an SiO₂ or an Si₃N₄. The reaction by-product may be an (NH₄)₂SiF₆. During a treatment of the substrate, the substrate is heated by the heater 324, and thus the reaction by-product may be removed from the substrate W.

While treating the substrate W with the process plasma, the controller 900 may control the third gas supply unit 660 to supply the first cleaning gas G3 to the remote plasma source 810. The controller 900 may control the remote plasma source 810 to excite the first cleaning gas G3 from the remote plasma source 810. The first cleaning plasma generated from the first cleaning gas G3 supplied to the remote plasma source 810 may be supplied to the exhaust space B through the supply port 830. Accordingly, the exhaust space B may be cleaned by the first cleaning plasma. The process by-products or the like deposited in the exhaust space B may be cleaned by the first cleaning plasma.

After the treatment of the substrate W using the process plasma is completed, the substrate W is taken out of the chamber 100. After the substrate W is taken out of the chamber 100, the controller 900 may control the fourth gas supply unit 680 to supply the second cleaning gas G2 to the plasma space A2. The controller 900 may control the second gas supply unit 640 to supply the second process gas G2 to the mixing space A3. Selectively, the controller 900 may control the second gas supply unit 640 to stop supplying the second process gas G2 to the mixing space A3. In addition, the top switch 426 may be controlled so that the top switch 426 is turned on so that the high-frequency power is applied to the top electrode 420. Accordingly, a generated second cleaning plasma may be supplied to the treating space A1 through the ion blocker 440 and the shower head 500. The second cleaning plasma from which ions are removed is supplied to the treating space A1, and the cleaning process for the treating space A1 may be performed.

In addition, even during a cleaning treatment of the treating space A1, the controller 900 may control the third gas supply unit 660 to supply the first cleaning gas G3 to the remote plasma source 810. The controller 900 may control the remote plasma source 810 to excite the first cleaning gas G3 from the remote plasma source 810. The first cleaning plasma generated from the first cleaning gas G3 supplied to the remote plasma source 810 may be supplied to the exhaust space B through the supply port 830. Accordingly, the exhaust space B may be cleaned by the first cleaning plasma. The process by-products or the like deposited in the exhaust space B may be cleaned by the first cleaning plasma.

According to the above-described embodiment of the inventive concept, a cleaning of the exhaust space B positioned under the treating space A1 may be performed even during a plasma treatment of the substrate W in the treating space A1. The process by-products deposited in the exhaust space B may be controlled. Accordingly, by maintaining an inside of the exhaust space B in a clean state, it is possible to induce a smooth airflow flow not only with respect to the exhaust space B but also to the treating space A1, the plasma space A2, and the mixing space A3. As an exhaust of each space is smoothly performed, a pressure inside the treating space A1 in which the substrate W is treated may be easily controlled. For this reason, if a plasma treatment process for the substrate W is performed, a process rate for the substrate W may be kept constant.

Furthermore, a large amount of process by-products or the like that may be generated by the process plasma may be deposited in the treating space A1. Accordingly, the treating of the substrate W using the process plasma is completed, and after the substrate W is taken out of the chamber 100, the cleaning of the treating space A1, which is a space in which the substrate W is treated, can be performed. Accordingly, a cleaning treatment may be performed on each of the treating space A1 and the exhaust space B.

In the above-described embodiment of the inventive concept, it has been described that the third gas supply unit 660 and the fourth gas supply unit 680 are respectively provided. However, the inventive concept is not limited thereto, and the third gas channel 664 which supplies the first cleaning gas G3 from the third gas supply unit 660 to the remote plasma source 810 may be branched to supply the first cleaning gas G3 to the plasma space A2. In addition, the first gas supply unit 620 may be configured to supply both the first process gas G1 and the second cleaning gas G4.

Hereinafter, a substrate treating method according to the inventive concept will be described. The substrate treating method of the inventive concept may include a chamber cleaning method for cleaning the chamber 100.

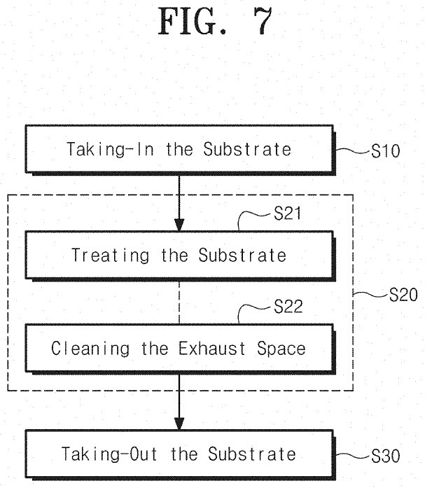

FIG. 7 is a flowchart of the substrate treating method according to an embodiment of the inventive concept.

Referring to FIG. 7, the substrate treating method in accordance with an embodiment of the inventive concept may include a substrate taking-in step S10, a process step S20, and a substrate taking-out step S30.

The substrate taking-in step S10 is a step in which the substrate W is taken into the chamber 100. The substrate W may be introduced into an inlet (not shown) formed at a side of the chamber 100 by a transfer robot (not shown). In an embodiment, if the inlet (not shown) is opened by a door (not shown), the transfer robot (not shown) returns the substrate W to the treating space A1 of the chamber 100. The transfer robot (not shown) puts the substrate W on the support unit 300. The substrate W is seated on the dielectric plate 320. The first switch 322b is turned on to form an electric field by an electrostatic force in the electrode 322, and the substrate W may be chucked to the dielectric plate 320.

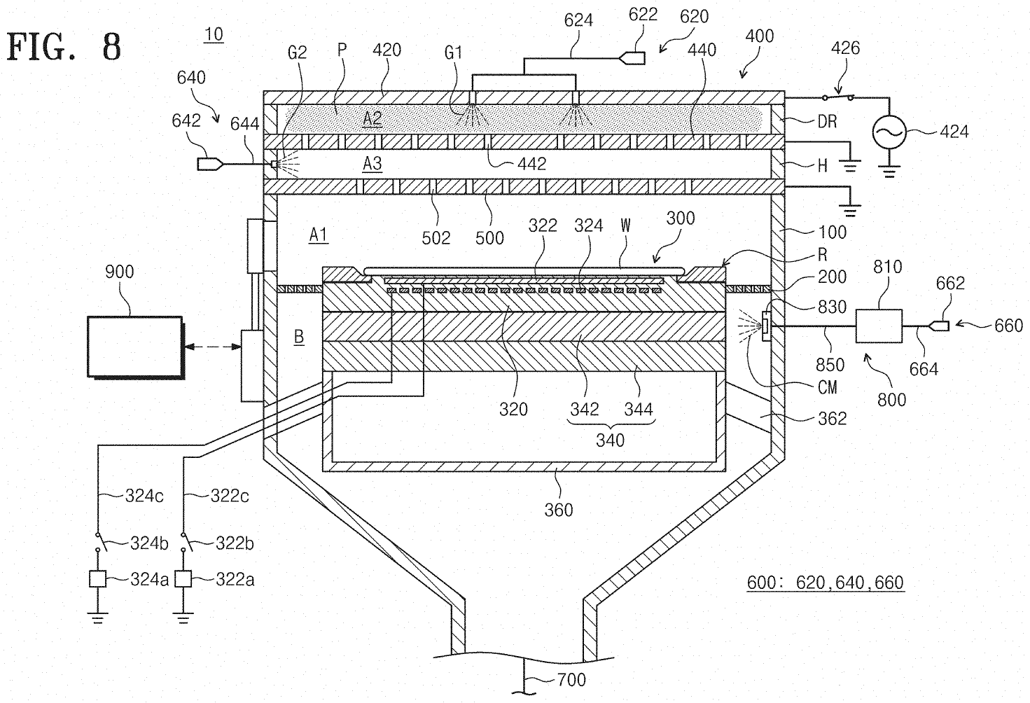

The process step S20 may include a substrate treating step S21 and an exhaust space cleaning step S22. At least a portion of a timing in which the substrate treating step S21 and the exhaust space cleaning step S22 are performed may overlap. That is, the substrate treating step S21 and the exhaust space cleaning step S22 may be performed together (see FIG. 8).

The substrate treating step S21 is a step in which a treating of the substrate W is performed using the process plasma P generated from the process gas supplied by the first gas supply unit 620 and/or the second gas supply unit 640. A process performed in the substrate treating step may include various processes for treating the substrate W using a plasma, such as an etching process for removing a thin film on the substrate W using the plasma P and an ashing process for removing a photoresist film.

In the substrate treating step S21, the first gas supply unit 620 supplies the first process gas G1 to the plasma space A2 defined as the plasma space. The first process gas G1 may be a fluorine-containing gas. For example, the first process gas G1 may be an NF₃. Selectively, the first process gas G1 may further include one or a plurality of an He, an Ar, an Xe, or an N₂. In addition, the high frequency power is applied to the top electrode 420. Accordingly, the first process gas G1 is excited by the top electrode 420 and the ion blocker 440, and the process plasma is generated in the plasma space A2. The process plasma generated in the plasma space A2 flows to the mixing space A3 through the ion blocker 440. In this process, the process plasma flows into the mixing space A3 in a state in which ions and/or electrons are removed by the through holes 442 formed in the grounded ion blocker 440. That is, the radical may flow in the mixing space A3.

The second gas supply unit 640 supplies the second process gas G2 to the mixing space A3. The second process gas G2 may be a gas containing a hydrogen. For example, the second process gas G2 may be an NH₃.

The radical present in the mixing space A3 and the second process gas G2 supplied to the mixing space A3 may be mixed and reacted. The reaction gas generated by a reaction of the second process gas G2 and radical flows through the shower head 500 into the treating space A1 and acts on the substrate W. For example, the reaction gas may include an NH₄F or an HF. The reaction gas reacts with the thin film on the substrate W, thereby forming a reaction by-product on the substrate. The thin film may be a material including a silicon. The thin film may be a silicon oxide or a silicon nitride. For example, the thin film may be an SiO₂ or an Si₃N₄. The reaction by-products may be an (NH₄)₂SiF₆. During a treatment of the substrate, the substrate is heated by the heater 324, and thus the reaction by-products may be removed from the substrate W.

The exhaust space cleaning step S22 is a step of cleaning the exhaust space B by supplying the first cleaning plasma, which is a cleaning medium CM, to the exhaust space B. The substrate treating step S21 and the exhaust space cleaning step S22 may be performed simultaneously. While the substrate W is being treated by the process plasma in the treating space A1, the first cleaning plasma may be supplied to the exhaust space B to perform the cleaning treatment on the exhaust space B. In addition, the exhaust space cleaning step S22 may be performed while performing the substrate taking-in step S10 and the substrate taking-out step S30.

The third gas supply unit 660 supplies the first cleaning gas G3 to the remote plasma source 810. The first cleaning gas G3 may include at least one of an O₂, an N₂, an F₂, an Ar, a CF₄, an NF₃ or combinations thereof. The remote plasma source 810 generates the first cleaning plasma by exciting the first cleaning gas G3. The first cleaning plasma is supplied to the supply port 830 positioned in the exhaust space B. The supply port 830 supplies the first cleaning plasma toward the exhaust space B to perform the cleaning treatment on process by-products deposited in the exhaust space B. Selectively, the first cleaning plasma from which ions are removed by the ion trap 870 may be supplied to the exhaust space B. Accordingly, process by-products or the like deposited in the exhaust space B may be removed by radicals.

The substrate taking-out step S30 is a step of taking out the substrate W to the outside of the chamber 100. The substrate W may be carried out to the outside of the chamber 100 by a transfer unit (not shown). Since the substrate taking-out step S30 may be performed in a reverse order of the substrate taking-in step S10, a redundant description thereof will be omitted.

According to the above-described embodiment of the inventive concept, the cleaning of the exhaust space B positioned under the treating space A1 may be performed even during the plasma treatment of the substrate W in the treating space A1. The process by-products deposited in the exhaust space B may be controlled. Accordingly, by maintaining the inside of the exhaust space B in a clean state, it is possible to induce a smooth airflow flow not only with respect to the exhaust space B but also to the treating space A1, the plasma space A2, and the mixing space A3. As the exhaust of each space is smoothly performed, the pressure inside the treating space A1 in which the substrate W is treated may be easily controlled. For this reason, if the plasma treatment process for the substrate W is performed, a process rate with respect to the substrate W may be kept constant.

In addition, the exhaust space cleaning step S22 may be further performed for a set time continuously after the substrate treating step S21 is performed. In addition, the exhaust space cleaning step S22 may be further performed for a set time before the substrate treating step S21 is performed.

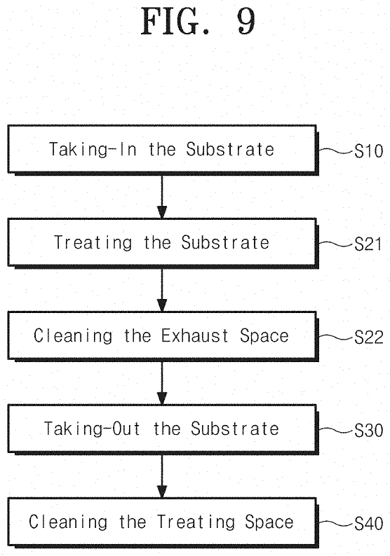

FIG. 9 is a flowchart of the substrate treating method according to another embodiment of the inventive concept

Referring to FIG. 9, the substrate treating method according to an embodiment of the inventive concept may include a substrate taking-in step S10, a substrate treating step S21, an exhaust space cleaning step S22, a substrate taking-out step S30, and a treating space cleaning step S40. Since descriptions of the substrate taking-in step S10 and the substrate taking-out step S30 are the same as or similar to those described above, a repeated description thereof will be omitted.

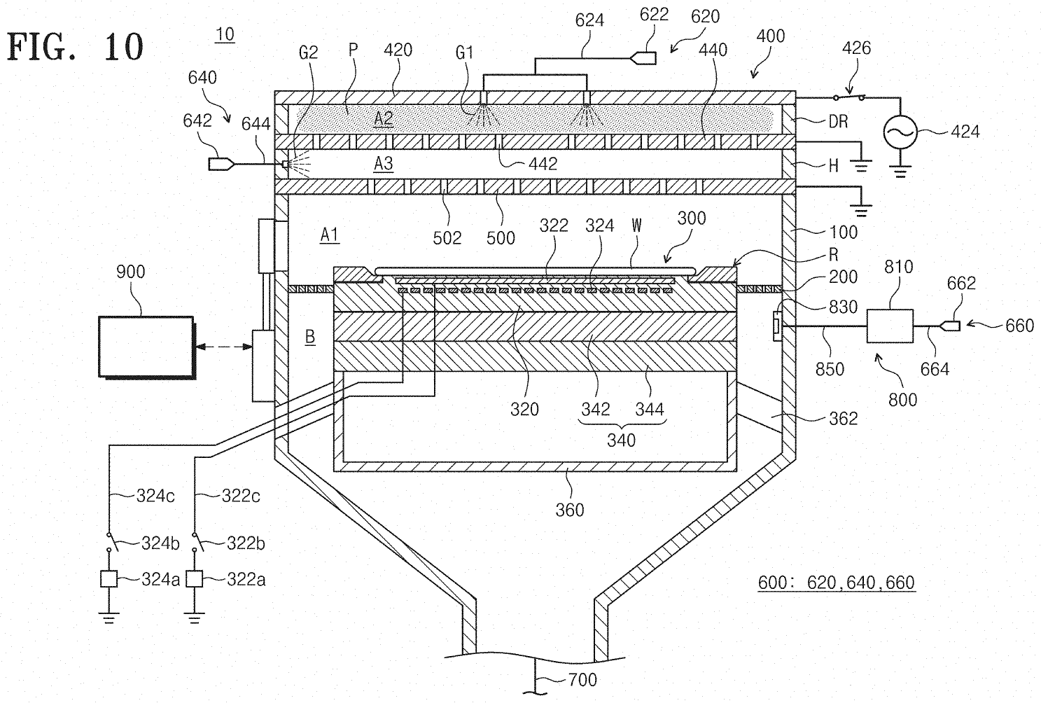

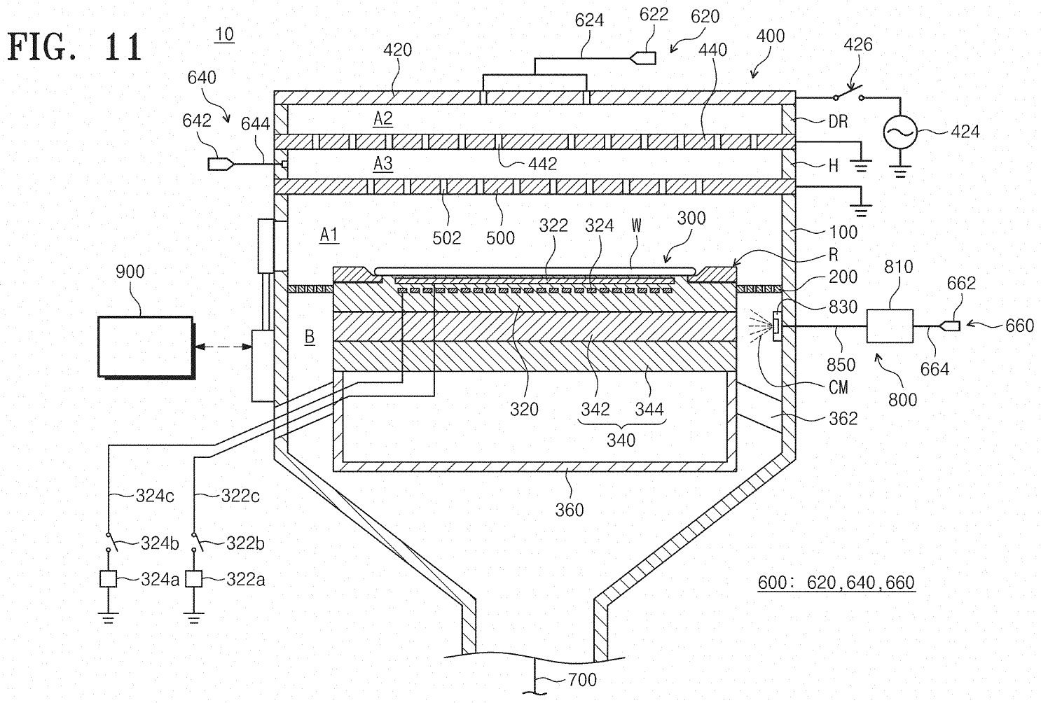

In the aforementioned example, the substrate treating step S21 and the exhaust space cleaning step S22 have been described as examples, but the inventive concept is not limited to it. For example, in the substrate treating method according to another embodiment of the inventive concept, the substrate treating step S21 may be performed (see FIG. 10), and then the exhaust space cleaning step S22 may be performed (see FIG. 11). Specifically, the exhaust space cleaning step S22 may be performed after the substrate treating step S21 is completed.

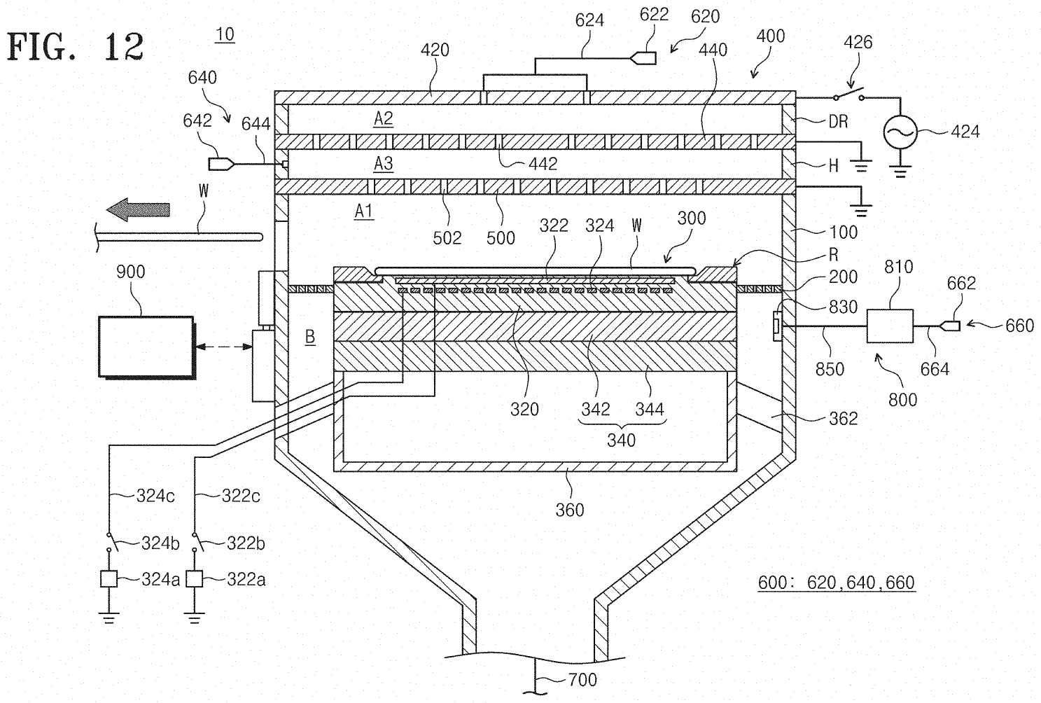

If the exhaust space cleaning step S22 is performed, the above-described cleaning medium CM is supplied to the exhaust space B, in which case the supplied cleaning medium CM may partially affect an atmospheric flow of the treating space A1. The effect of the atmospheric flow in the treating space A1 due to a supply of the cleaning medium CM may be generally prevented by the exhaust baffle 200, but this effect may greatly affect the treating of the substrate W depending on a process precision required for the substrate W to be treated. Accordingly, the substrate treating method according to another embodiment of the inventive concept prevents the above-described substrate W treatment from being affected by performing the exhaust space cleaning step S22 after the substrate treating step S21 is completed. In addition, the exhaust space cleaning step S22 is performed before the substrate taking-out step S30 (see FIG. 12) of taking out the substrate W from the treating space A1 to minimize an additional time required to clean the exhaust space B.

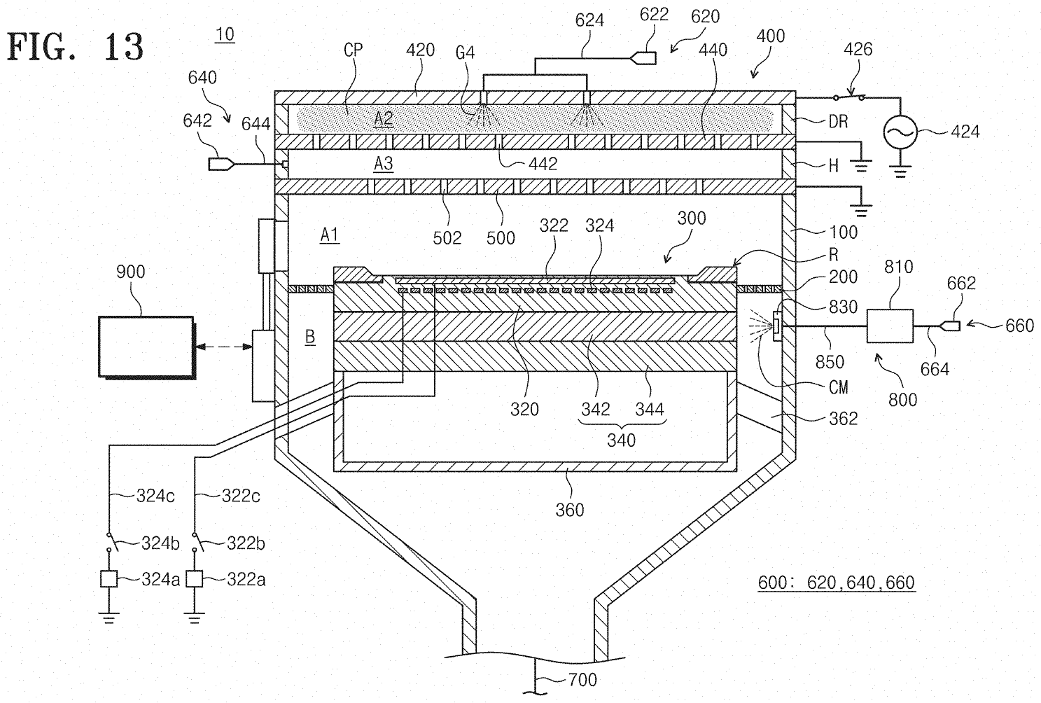

If the substrate taking-out step S30 is completed, the substrate W to be treated may not exist in the treating space A1. If the substrate taking-out step S30 is completed, a cleaning of the treating space A1 may be required. After the substrate taking-out step S30, the treating space cleaning step S40 may be performed (see FIG. 13).

In the treating space cleaning step S40, the first gas supply unit 620 may supply the second cleaning gas G4 to the plasma space A2 to generate the second cleaning plasma CP, which is a cleaning medium. In the treating space cleaning step S40, the second cleaning plasma CP may sequentially pass through the plasma space A2, the mixing space A3, the treating space A1, and the exhaust space B to clean the plasma space A2, the mixing space A3, and the exhaust space B.

The treating space cleaning step S40 may be performed after the substrate taking-out step S30. The treating space cleaning step S40 may perform the cleaning treatment with respect to on the treating space A1. In the treating space cleaning step S40, the second cleaning gas G4 is supplied to the plasma space A2. In an embodiment, the fourth gas supply unit 680 may supply the second cleaning gas G4 to the plasma space A2. The second cleaning gas G4 may include at least one of an O₂, an N₂, an F₂, a Cl₂, an Ar, a CF₄, an NF₃, or combinations thereof.

The second cleaning gas G4 supplied to the plasma space A2 is excited by the top electrode 420 and the ion blocker 440 to generate the second cleaning plasma in the plasma space A2. The second gas supply unit 640 may supply the second process gas G2 to the mixing space A3. Selectively, the second gas supply unit 640 may stop supplying the second process gas G2 to the mixing space A3. The second cleaning plasma generated in the plasma space A2 flows into the mixing space A3 through a through hole 442 formed in the grounded ion blocker 440. Accordingly, the second cleaning plasma is supplied to the mixing space A3 in a state in which ions are removed. The second cleaning plasma from which ions flowing into the mixing space A3 are removed flows into the treating space A1 through the hole 502 formed in the shower head 500. In the substrate treating step S21, process by-products or the like generated inside the treating space A1 may be removed by a second cleaning plasma (i.e., radical) from which ions are removed.

In addition, selectively, while the treating space cleaning step S40 is performed, the exhaust space cleaning step S22 may also be performed. The process by-products attached to a narrow space between the support unit 300 and the exhaust baffle 200 may not be properly removed by the second cleaning plasma CP, and the exhaust space cleaning step S22 may be performed together with the treating space cleaning step S40 to solve this problem.

According to the above-described embodiment of the inventive concept, the cleaning of the exhaust space B positioned under the treating space A1 may be performed even during the plasma treatment of the substrate W in the treating space A1. The process by-products deposited in the exhaust space B may be controlled. Accordingly, by maintaining the inside of the exhaust space B in a clean state, it is possible to induce a smooth airflow flow not only with resepct to the exhaust space B but also to the treating space A1, the plasma space A2, and the mixing space A3. As the exhaust of each space is smoothly performed, the pressure inside the treating space A1 in which the substrate W is treated may be easily controlled. For this reason, if the plasma treatment process for the substrate W is performed, a process rate for the substrate W may be kept constant.

Furthermore, a large amount of process by-products or the like that may be generated by the process plasma may be deposited in the treating space A1. Accordingly, the treatment of the substrate W using the process plasma is completed, and after the substrate W is taken out of the chamber 100, the cleaning of the treating space A1, which is a space in which the substrate W is treated, can be performed. Accordingly, the cleaning treatment for each of the treating space A1 and the exhaust space B may be performed simultaneously.

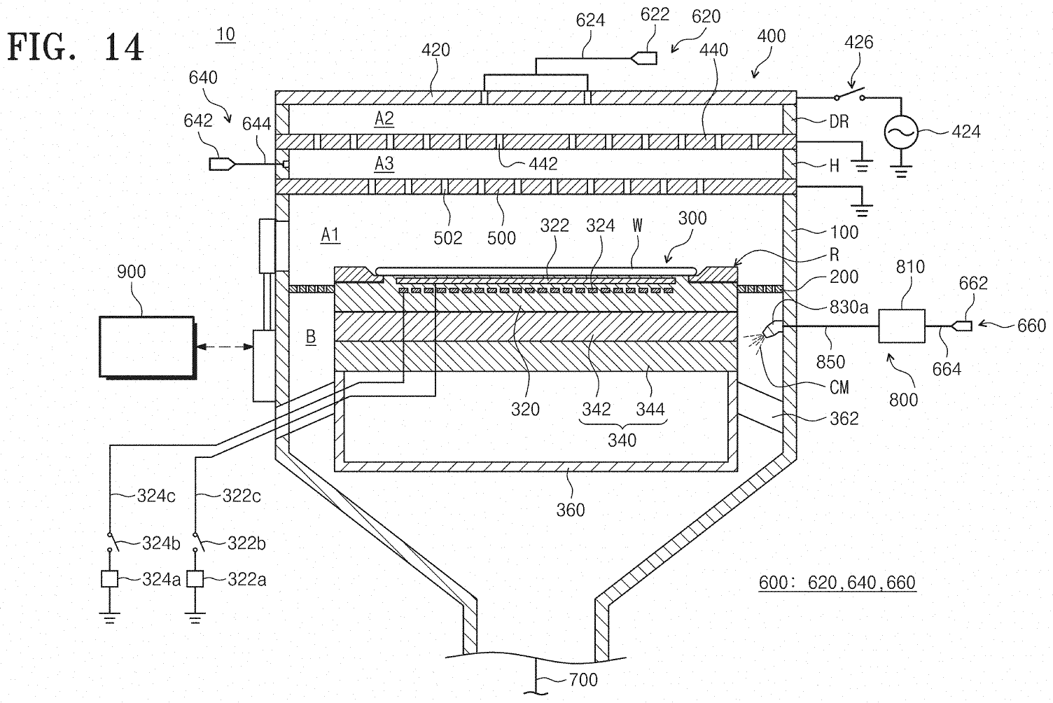

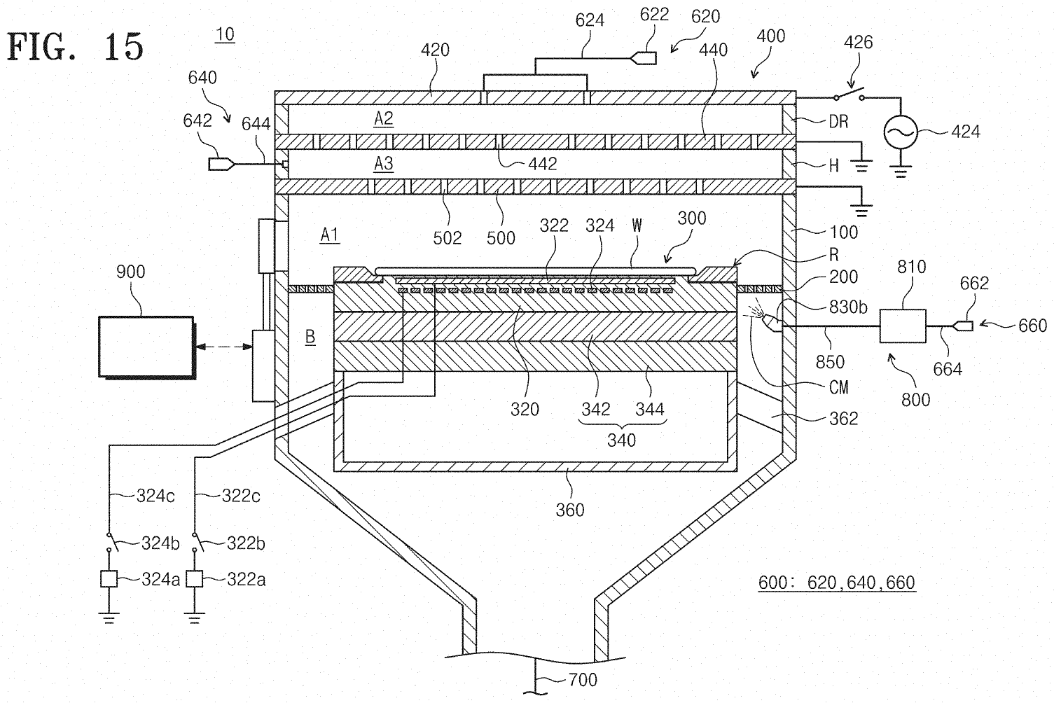

In the above-described example, the supply port 830 supplies the cleaning medium CM in a lateral direction, but is not limited thereto. For example, as illustrated in FIG. 14, the supply port 830a according to another embodiment may supply the cleaning medium CM in a downwardly inclined direction. Also, as illustrated in FIG. 15, the supply port 830b according to another embodiment may supply the cleaning medium CM in an upwardly inclined direction. If the cleaning medium CM is supplied in the inclined direction as described above, an area of which the support unit 300 is cleaned may be larger.

In addition, in the above example, the exhaust space cleaning step S22 is performed with the substrate treating step S21 or after the substrate treating step S21 is completed, but is not limited thereto. For example, the exhaust space cleaning step S22 may be performed while the substrate taking-in step S10 and the substrate taking-out step S30 are performed.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

1-10. (canceled)

11. A chamber cleaning method for cleaning a chamber having an inner space, the inner space dividing into a treating space for treating a substate by an exhaust baffle and an exhaust space, the treating space and the exhaust space fluidly communicating through a through hole formed at the exhaust baffle, the method comprising cleaning the exhaust space by transferring a cleaning plasma to the exhaust space among the treating space and the exhaust space.

12. The method of claim 11, wherein the cleaning the exhaust space is performed while the substrate is treated by transferring a process plasma to the treating space.

13. The method of claim 11, wherein the cleaning the exhaust space is performed after the substrate is treated by transferring a process plasma to the treating space.

14. The method of claim 11 further comprising cleaning the treating space among the treating space and the exhaust space by transferring the cleaning plasma to the treating space to clean the treating space and the exhaust space.

15. The method of claim 14, wherein the cleaning the treating space is performed after the substrate is taken out from the treating space.

16-20. (canceled)
